(19) United States
(12) Patent Application Publication
(10) Pub. No.: US 2025/0380572 A1
(43) Pub. Date: Dec. 11, 2025

(54) ARRAY SUBSTRATE, DISPLAY PANEL, AND METHOD FOR FABRICATING AN ARRAY SUBSTRATE

(71) Applicants: YUNNAN INVENSIGHT OPTOELECTRONICS TECHNOLOGY CO., LTD., KUNMING, YUNNAN (CN); BOE TECHNOLOGY GROUP CO., LTD., Beijing (CN)

(72) Inventors: Yunhao ZHANG, Beijing (CN); Hongtao YU, Beijing (CN); Dongdong SU, Beijing (CN); Zongshun YANG, Beijing (CN); Cao WU, Beijing (CN); Kuanta HUANG, Beijing (CN); Weiliang BU, Beijing (CN); Jixing WANG, Beijing (CN); Chao YANG, Beijing (CN)

(21) Appl. No.: 18/580,556

(22) PCT Filed: Mar. 1, 2023
(86) PCT No.: PCT/CN2023/078961

§ 371 Date: Dec. 4, 2024

(51) Int. Cl. H10K 59/122; H10K 59/12; H10K 102/00

(52) U.S. Cl. CPC H10K 59/122; H10K 59/1201; H10K 2102/351

(57) ABSTRACT

The present disclosure relates to an array substrate, a display panel, and a method for fabricating an array substrate. The array substrate includes a base substrate; a pixel defining layer with an opening on the base substrate; a light emitting device layer including first electrodes between the base substrate and the pixel defining layer, wherein an orthographic projection of the first electrode on the base substrate overlaps at least partially with an orthographic projection of the opening on the base substrate; and at least one protrusion on the base substrate and around the first electrode, wherein the light emitting device layer has a gap, and wherein an orthographic projection of the gap on the base substrate overlaps at least partially with an orthographic projection of the protrusion on the base substrate.

### TECHNICAL FIELD

The present disclosure relates to the technical field of displaying, and more particularly, to an array substrate, a display panel, and a method for fabricating an array substrate.

### BACKGROUND

The Organic Light-Emitting Diode (OLED) display panels have the advantages of self-illumination, high efficiency, bright colors, etc., and have been gradually applied to large-area displays, lighting, and in-vehicle displays.

### SUMMARY

Embodiments of the present invention provide a method for fabricating an array substrate. The array substrate includes: a base substrate; a pixel defining layer with an opening on the base substrate; a light emitting device layer including first electrodes between the base substrate and the pixel defining layer, wherein an orthographic projection of the first electrode on the base substrate overlaps at least partially with an orthographic projection of the opening on the base substrate; and at least one protrusion on the base substrate and around the first electrode, wherein the light emitting device layer has a gap, and wherein an orthographic projection of the gap on the base substrate overlaps at least partially with an orthographic projection of the protrusion on the base substrate.

In some embodiments, the first electrode has a first surface facing the base substrate and a second surface facing away from the base substrate, and the protrusion has a third surface facing the base substrate and a fourth surface facing away from the base substrate, wherein, compared with the second surface of the first electrode, the fourth surface of the protrusion is closer to the base substrate.

In some embodiments, in a direction away from a surface of the base substrate provided with the first electrode, a height difference between the second surface of the first electrode and the fourth surface of the protrusion is in a range of 90 Å to 240 Å.

In some embodiments, the height difference between the second surface of the first electrode and the fourth surface of the protrusion is in a range of 110 Å to 200 Å.

In some embodiments, the protrusion surrounds the first electrode.

In some embodiments, the protrusion is in contact with the first electrode.

In some embodiments, the light emitting device layer includes a hole injection layer, and wherein the hole injection layer has the gap.

In some embodiments, the first electrode includes a first conductive layer and a second conductive layer, and wherein the second conductive layer covers a surface of the first conductive layer away from the base substrate and a side surface of the first conductive layer.

In some embodiments, the array substrate further includes a drive circuit layer provided between the base substrate and the first electrode, wherein the second conductive layer further covers a side surface of the drive circuit layer. In some embodiments, the second conductive layer extends to the protrusion.

In some embodiments, a side of the base substrate close to the first electrode has a recessed portion and a non-recessed portion, the recessed portion being between the first conductive layer, and wherein an orthographic projection of the first conductive layer on the base substrate falls within the non-recessed portion. The non-recessed portion includes a first sub-portion projecting in a direction perpendicular to the base substrate and with respect to the recessed portion toward the first conductive layer, wherein the first sub-portion has a fifth surface facing toward the first conductive layer and a sixth surface facing away from the first conductive layer, and wherein an orthographic projection of the fifth surface on the base substrate falls within an orthographic projection of the sixth surface on the base substrate.

In some embodiments, the first sub-portion further includes a side surface connecting the fifth surface and the sixth surface, and wherein the second conductive layer further covers the side surface of the first sub-portion and extending to the protrusion.

In some embodiments, an angle between the side surface of the first sub-portion and the sixth surface is an acute angle.

In some embodiments, the recessed portion has an intermediate portion between the protrusions and an edge portion disposed between the protrusions and on either side of the intermediate portion, and wherein, in a direction perpendicular to the base substrate, a height of the edge portion is lower than a height of the intermediate portion.

In some embodiments, the pixel defining layer covers a side surface of the first electrode and a surface of the protrusion away from the base substrate and a side surface of the protrusion.

In some embodiments, a height of the protrusion in a direction perpendicular to the base substrate is greater than a minimum width of the protrusion in a direction parallel to the base substrate.

In some embodiments, the protrusion includes at least one of an organic material or an inorganic material.

In some embodiments, an orthographic projection of the third surface of the protrusion on the base substrate overlies an orthographic projection of the fourth surface of the protrusion on the base substrate.

In some embodiments, a thickness of the pixel defining layer is in a range of about 0.05 μm to 0.08 μm.

In some embodiments, in a direction parallel to the base substrate, the protrusion has a width in a range of 0.02 μm to 0.03 μm.

In some embodiments, the light-emitting device layer includes a light-emitting function layer away from the first electrode, and wherein a thickness of the projection is greater than a thickness of the light-emitting function layer.

In some embodiments, the array substrate further includes a second electrode provided on a surface of the light emitting device layer away from the base substrate.

Some embodiments of the present disclosure also provide a display panel. The display panel includes an array substrate as described above.

Some embodiments of the present disclosure also provide a method for fabricating an array substrate. The method includes: providing a base substrate; forming a pixel defining layer with an opening on the base substrate; forming a first electrode between the base substrate and the pixel defining layer, wherein an orthographic projection of the first electrode on the base substrate overlaps at least partially with an orthographic projection of the opening on the base substrate; forming at least one protrusion the base substrate and around the first electrode; and forming a light emitting device layer on the pixel defining layer, wherein the light emitting device layer has a gap, and wherein an orthographic projection of the gap on the base substrate overlaps at least partially with an orthographic projection of the protrusion on the base substrate.

In some embodiments, the first electrode has a first surface facing the base substrate and a second surface facing away from the base substrate, and the protrusion has a third surface facing the base substrate and a fourth surface facing away from the base substrate, and wherein the fourth surface of the protrusion is closer to the base substrate than the second surface of the first electrode.

In some embodiments, in a direction away from a surface of the base substrate on which the first electrode is provided, a height difference between the second surface of the first electrode and the fourth surface of the protrusion may be between about 110 Å˜200 Å.

In some embodiments, the light emitting device layer includes a hole injection layer, and wherein the hole injection layer has the gap.

In some embodiments, the first electrode includes a first conductive layer and a second conductive layer, wherein the second conductive layer covers a surface of the first conductive layer away from the base substrate and a side surface of the first conductive layer, wherein forming a first electrode and a protrusion includes: forming the first conductive layer on the base substrate; forming a second conductive material layer on the first conductive layer; and patterning the second conductive material layer to form the second conductive layer and the protrusion.

In some embodiments, forming a second conductive material layer includes forming the second conductive material layer on a surface of the first conductive layer away from the base substrate, a side surface of the first conductive layer and an exposed surface of the base substrate. Wherein, forming the second conductive layer and the protrusion includes: forming a photoresist layer on the second conductive material layer; patterning the photoresist layer to form a photoresist-retained portion corresponding to the second conductive layer and a photoresist-removed portion exposing the second conductive material layer; etching an exposed portion of the second conductive material layer to form the second conductive portion and to form the protrusion; and removing the photoresist-retained portion.

In some embodiments, the thickness of the photoresist layer is between about 0.35 μm to 0.6 μm, and the etching of the exposed second conductive material layer is performed at a pressure of about 15-17 millitorr and in an atmosphere with a fluorine content of more than 90%.

In some embodiments, forming the pixel defining layer includes: forming a pixel-defining material layer on the second conductive layer, the protrusion, and an exposed surface of the base substrate; and patterning the pixel-defining material layer to form a pixel defining layer with the opening.

In some embodiments, the method further includes forming a hole injection layer on the pixel defining layer, wherein the hole injection layer has the gap.

### BRIEF DESCRIPTION OF THE DRAWINGS

In order to explain the technical solutions of the embodiments of the present disclosure more clearly, the drawings of the embodiments will be briefly described below. It should be understood that the drawings described below only relate to some embodiments of the present disclosure, instead of being a limit to the present disclosure, in which:

FIG. 1 is a schematic view of an array substrate according to an embodiment of the present disclosure;

FIG. 2 is a schematic view of an array substrate according to an embodiment of the present disclosure;

FIG. 3A is a schematic view of an array substrate according to an embodiment of the present disclosure;

FIG. 3B is a schematic view of an array substrate according to an embodiment of the present disclosure;

FIG. 4 is a schematic view of an array substrate according to an embodiment of the present disclosure;

FIG. 5 shows a partial schematic view of the array substrate of FIG. 4;

FIG. 6 is a schematic view of a display panel according to an embodiment of the present disclosure;

FIG. 7 is a schematic flow view of a method for fabricating an array substrate according to an embodiment of the present disclosure;

FIG. 8 is a schematic view of a portion of a flow of a method for fabricating an array substrate according to an embodiment of the present disclosure;

FIG. 9 is a schematic view of a portion of a flow of a method for fabricating an array substrate according to an embodiment of the present disclosure;

FIG. 10 is a schematic view of a portion of a flow of a method for fabricating an array substrate according to an embodiment of the present disclosure;

FIGS. 11A-FIG. 11I are flow views of a method for fabricating an array substrate according to embodiments of the text of the present disclosure.

### DETAILED DESCRIPTION

In order to make the objectives, technical solutions, and advantages of the embodiments of the present disclosure clearer, the technical solutions of the embodiments of the present disclosure will be described clearly and completely in conjunction with the accompanying drawings. Obviously, the described embodiments are part of the embodiments of the present disclosure, rather than all of the embodiments. Based on the described embodiments of the present disclosure, all other embodiments obtained by those skilled in the art without creative labor are also belonging to the protection scope of the present disclosure.

When the elements and the embodiments thereof of the present application are introduced, the articles “a/an”, “one”, “the” and “the” are intended to represent the existence of one or more elements. The expressions “comprise”, “include”, “contain” and “have” are intended as inclusive and mean that there may be other elements besides those listed.

For purposes of the description hereinafter, the terms “upper”, “lower”, “right”, “left”, “vertical”, “horizontal”, “top”, “bottom”, and derivatives thereof shall relate to the invention, as it is oriented in the drawing figures. The terms “overlying”, “atop”, “positioned on” or “positioned atop” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected with or without any additional elements at the interface of the two elements.

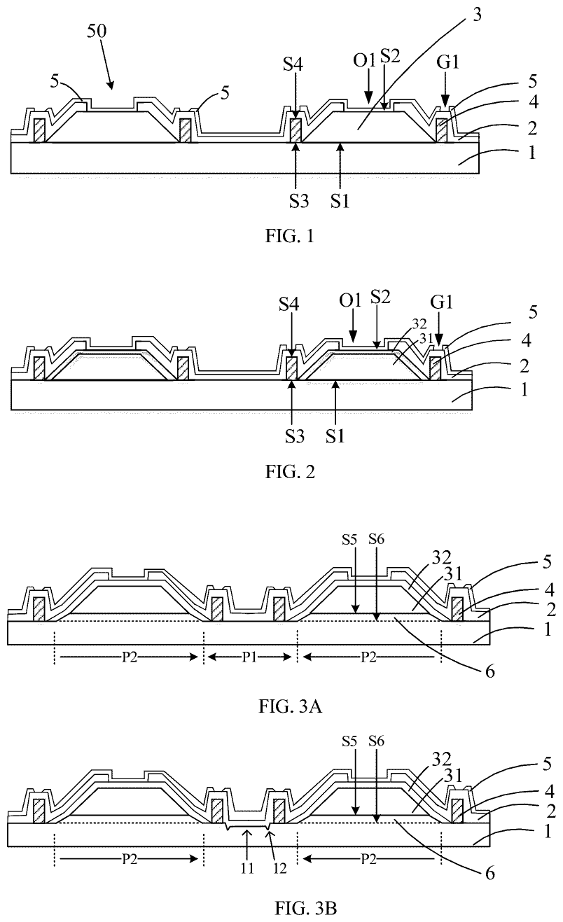

FIG. 1 is a schematic view of an array substrate according to an embodiment of the present disclosure. As shown in FIG. 1, the array substrate according to an embodiment of the present disclosure includes: a base substrate 1, a pixel defining layer 2 with an opening O1 on the base substrate 1, a light-emitting device layer 50 including a plurality of first electrodes 3, and at least one protrusion 4 on the base substrate 1 and around the first electrodes 3. Wherein the first electrodes 3 are between the base substrate 1 and the pixel defining layer 2, and wherein an orthographic projection of the first electrode 3 on the base substrate 1 overlaps at least partially with an orthographic projection of the opening on the base substrate 1. The light emitting device layer has a gap G1, and wherein an orthographic projection of the gap G1 on the base substrate 1 overlaps at least partially with an orthographic projection of the protrusion 4 on the base substrate 1.

The inventors have found that in light emitting device (LED) product structures, especially in single white light emitting device (WLED) product structures, the crosstalk effect of the LED layers (especially the hole transporting layer) between sub-pixels often results in leakage of electricity, which can lead to color crosstalk. In the embodiments of the present disclosure, it is possible to make the portion of the light emitting device layer above the protrusion discontinuous, thereby solving the problem of color crosstalk caused by leakage between sub-pixels, and avoiding cathode puncture.

The pixel defining layer may define sub-pixels of the array substrate through openings. In some embodiments, projections may be located on both sides of a first electrode. In other embodiments, a projection or projections may be located on one side of a first electrode. The pixel defining layer may include a silicone oxide compound. The projection may include a carbon-containing compound.

The first electrode 3 may have a first surface S1 facing the base substrate 1 and a second surface S2 facing away from the base substrate 1. The protrusion 4 may have a third surface S3 facing the base substrate 1 and a fourth surface S4 facing away from the base substrate 1. Compared with the second surface S2 of the first electrode 3, the fourth surface S4 of the protrusion may be closer to the base substrate. This enables better formation of gaps of the light emitting device layers, solving the problem of color crosstalk caused by leakage between sub-pixels and avoiding cathode puncture.

In some embodiments, in a direction perpendicular to the base substrate 1, a height difference between the second surface S2 of the first electrode 3 and the fourth surface S4 of the protrusion 4 is in a range of 90 Å to 240 Å. Further, the height difference between the second surface of the first electrode and the fourth surface of the protrusion may be in a range of 110 Å˜200 Å. Thereby, the problem of color crosstalk can be solved while the phenomenon of cathode puncture can be better avoided.

In some embodiments, the protrusion may surround the first electrode, obtaining a better solution to the problem of color crosstalk.

As shown in FIG. 1, in some embodiments, the protrusion is in contact with the first electrode 3. The light emitting device layer may further include a light emitting function layer 5.

The inventors have found that a hole injection layer tends to cause leakage between adjacent sub-pixels, thereby causing color crosstalk problems. The light emitting function layer 5 may include a hole injection layer, and the hole injection layer may have a gap G1. The material of the hole injection layer tends to have a relatively poor climbing ability, whereby the difference in height may cause the hole injection layer to break. This makes the hole injection layer between adjacent sub-pixels discontinuous, thereby avoiding the problem of color crosstalk caused by the hole injection layer between adjacent sub-pixels. The hole injection layer may include at least one of the following materials: CuPc (polyester carbonate), TiOPc, m-MTDATA and 2-TNATA.

FIG. 2 is a schematic view of an array substrate according to an embodiment of the present disclosure. As shown in FIG. 2, the first electrode 3 may include a first conductive layer 31 and a second conductive layer 32. The second conductive layer 32 covers a surface of the first conductive layer 31 away from the base substrate and a side surface of the first conductive layer. The second conductive layer 32 may also extend to the projection 4 and may be in contact with the projection 4.

FIGS. 3A-FIG. 3B are schematic views of an array substrate according to some embodiments of the present disclosure. As shown in FIG. 3A, the base substrate 1 close to the first electrode of an array substrate according to some embodiments has a recessed portion P1 and a non-recessed portion P2, the recessed portion P1 is between the first conductive layer 31, and wherein an orthographic projection of the first conductive layer 31 on the base substrate 1 falls within the non-recessed portion P2.

The non-recessed portion P2 includes a first sub-portion 6 projecting in a direction perpendicular to the base substrate 1 and with respect to the recessed portion P1 toward the first conductive layer 31, wherein the first sub-portion 6 has a fifth surface S5 facing toward the first conductive layer 31 and a sixth surface S6 facing away from the first conductive layer 31, and wherein an orthographic projection of the fifth surface S5 on the base substrate falls within an orthographic projection of the sixth surface S6 on the base substrate. The area of the fifth surface S5 may be smaller than the area of the sixth surface S6.

The first sub-portion 6 further includes a side surface connecting the fifth surface and the sixth surface. As shown in FIGS. 3A-3B, the second conductive layer 32 further covers the side surface of the first sub-portion 6 and extends to the protrusion 4.

An angle between the side surface of the first sub-portion and the sixth surface may be an acute angle. For example, the angle may be less than or equal to 45 degrees. For example, the angle may be 40 degrees, 30 degrees, or 20 degrees.

As shown in FIG. 3B, the recessed portion P1 may have an intermediate portion 11 between the protrusions 4 and an edge portion 12 disposed between the protrusions 4 and disposed on either side of the intermediate portion 11. In a direction perpendicular to the base substrate 1, a height of the edge portion 12 is lower than a height of the intermediate portion 11.

The height of the protrusion 4 in the direction perpendicular to the base substrate 1 may be greater than the minimum width of the protrusion in the direction parallel to the base substrate. The orthographic projection of the third surface S3 of the protrusion on the base substrate 1 covers the orthographic projection of the fourth surface S4 of the protrusion 4 on the base substrate 1.

As shown in FIG. 3A-FIG. 3B, the pixel defining layer 2 covers a side surface of the first electrode 3 and a surface of the protrusion 4 away from the base substrate and a side surface of the protrusion. When the protrusion includes an electrically conductive material, such a setting enables the protrusion to be insulated from the light emitting device layer thereon.

In some embodiments, the protrusion includes at least one of an organic material or an inorganic material. In a direction perpendicular to the base substrate, the thickness of the protrusion 4 may be greater than the thickness of the light-emitting function layer 5.

In some embodiments, the thickness of the pixel defining layer 2 may be between about 0.05 μm to 0.08 μm. In some embodiments, in a direction parallel to the base substrate, the width of the protrusion 4 is between about 0.02 μm to 0.03 μm.

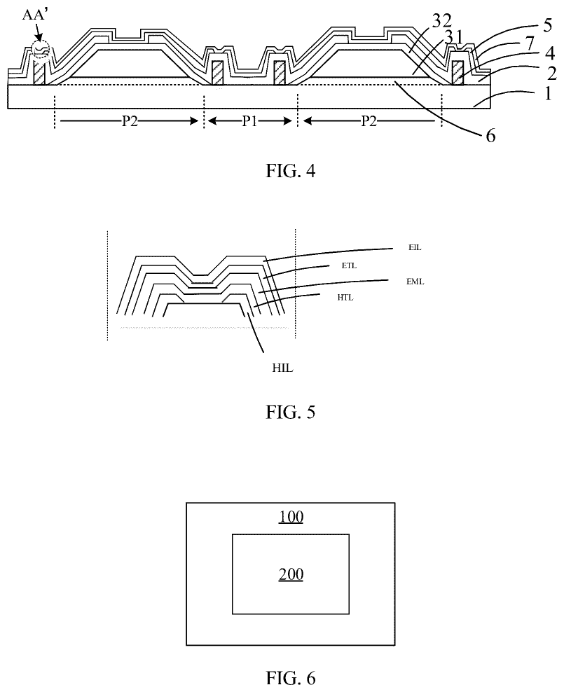

FIG. 4 is a schematic view of an array substrate according to an embodiment of the present disclosure. As shown in FIG. 4, the light-emitting device layer according to an embodiment of the present disclosure may further include a second electrode 7 provided on a surface of the light-emitting function layer 5 away from the base substrate. The first electrode 3 may be used as an anode of the light-emitting device, and the second electrode 7 may be used as a cathode of the light-emitting device.

FIG. 5 is a partial schematic view of the array substrate of FIG. 4. FIG. 5 exemplarily illustrates a partial structure of the AA′ region of FIG. 4. As shown in FIG. 5, the light emitting device layer 5 may include a hole injection layer HIL1, a hole transport layer HTL2 over the hole injection layer HIL, a light emitting layer EML3 over the hole transport layer HTL, an electron transport layer ETL4 over the light emitting layer EML, and an electron injection layer EIL5 over the electron transport layer ETL. In some embodiments of the present invention, the hole transport layer may have a gap that capable of solving the problem of color crosstalk between neighboring sub-pixels. The remaining layers of the light emitting device layer 5, may not have a gap or may also have a gap.

FIG. 6 shows a schematic view of a display panel according to an embodiment of the present disclosure. As shown in FIG. 6, the display panel 100 according to an embodiment of the present disclosure may include an array substrate 200. The array substrate 200 may be the array substrate illustrated in FIGS. 1-FIG. 5.

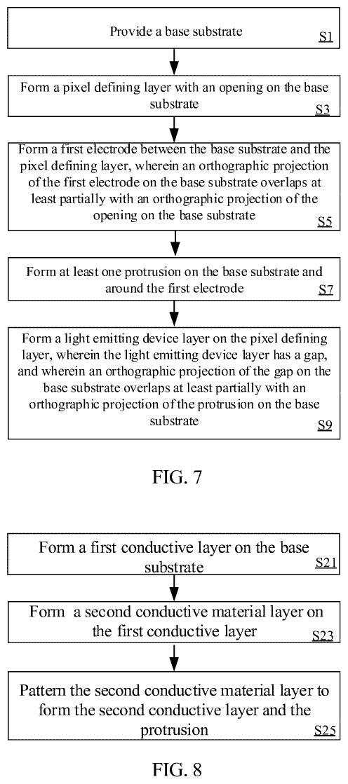

FIG. 7 shows a flow chart of a method for fabricating an array substrate according to an embodiment of the present disclosure. As shown in FIG. 7, a method for fabricating an array substrate according to an embodiment of the present disclosure may include:
S1. providing a base substrate;
S3. forming a pixel defining layer with an opening on the base substrate;
S5. forming a first electrode between the base substrate and the pixel defining layer, wherein an orthographic projection of the first electrode on the base substrate overlaps at least partially with an orthographic projection of the opening on the base substrate;
S7. forming at least one protrusion on the base substrate and around the first electrode; and
S9. forming a light emitting device layer on the pixel defining layer, wherein the light emitting device layer has a gap, and wherein an orthographic projection of the gap on the base substrate overlaps at least partially with an orthographic projection of the protrusion on the base substrate.

In the embodiments of the present disclosure, generating the protrusions does not add an extra step, but instead saves the process flow, and achieves the unexpected effect of solving the problem of color crosstalk caused by leakage between sub-pixels and avoiding the cathode puncture phenomenon.

In some embodiments, the first electrode has a first surface facing the base substrate and a second surface facing away from the base substrate, and the protrusion has a third surface facing the base substrate and a fourth surface facing away from the base substrate. Wherein the fourth surface of the protrusion is closer to the base substrate than the second surface of the first electrode. This enables better formation of spacers in the light emitting device layers, solves the problem of color crosstalk due to leakage between sub-pixels, and avoids cathode puncture phenomenon.

In some embodiments, in a direction away from a surface of the base substrate on which the first electrode is provided, a height difference between the second surface of the first electrode and the fourth surface of the protrusion may be between about 90 Å˜240 Å. Further, the height difference between the second surface of the first electrode and the fourth surface of the protrusion may be between about 110 Å to 200 Å. Thereby, the problem of color crosstalk can be solved while the phenomenon of cathode puncture can be better avoided.

The light emitting device layer may include a hole injection layer, and wherein the hole injection layer has the gap. The inventors have found that a hole injection layer tends to cause leakage between adjacent sub-pixels, thereby causing color crosstalk problems. The light emitting function layer 5 may include a hole injection layer, and the hole injection layer may have a gap G1. The material of the hole injection layer tends to have a relatively poor climbing ability, whereby the difference in height may cause the hole injection layer to break. This makes the hole injection layer between adjacent sub-pixels discontinuous, thereby avoiding the problem of color crosstalk caused by the hole injection layer between adjacent sub-pixels. The hole injection layer may include at least one of the following materials: CuPc (polyester carbonate), TiOPc, m-MTDATA and 2-TNATA.

The first electrode may include a first conductive layer and a second conductive layer. The second conductive layer covers a surface of the first conductive layer away from the base substrate and a side surface of the first conductive layer.

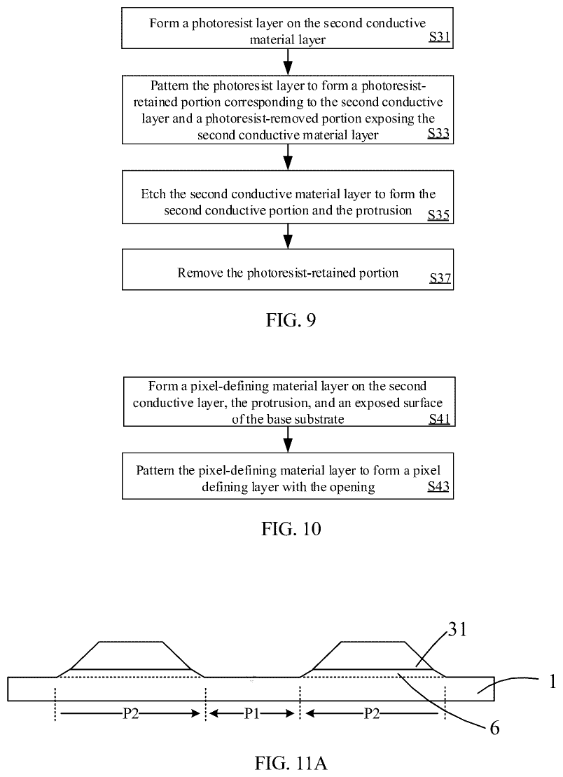

FIG. 8 shows a schematic flow chart of a portion of a method for fabricating an array substrate according to an embodiment of the present disclosure. As shown in FIG. 8, in some embodiments, forming a first electrode and a protrusion includes:
S21. forming a first conductive layer on the base substrate;
S23. forming a second conductive material layer on the first conductive layer; and
S25. patterning the second conductive material layer to form the second conductive layer and the protrusion.

In some embodiments, forming a second conductive material layer includes forming the second conductive material layer on a surface of the first conductive layer away from the base substrate, a side surface of the first conductive layer and an exposed surface of the base substrate.

FIG. 9 shows a schematic flow chart of a portion of a method for fabricating an array substrate according to an embodiment of the present disclosure. As shown in FIG. 9, forming the second conductive layer and the protrusion may include:
S31. forming a photoresist layer on the second conductive material layer;
S33. patterning the photoresist layer to form a photoresist-retained portion corresponding to the second conductive layer and a photoresist-removed portion exposing the second conductive material layer, wherein “corresponding” in this context means that an orthographic projection of the photoresist-retained portion on the base substrate overlaps at least partially with an orthographic projection of the second conductive layer on the base substrate.
S35, etching an exposed portion of the second conductive material layer to form the second conductive portion and to form the protrusion; and
S37. removing the photoresist-retained portion.

The thickness of the photoresist layer may be between about 0.35 μm to 0.6 μm.

FIG. 10 shows a schematic flow chart of a portion of a method for fabricating an array substrate according to an embodiment of the present disclosure. As shown in FIG. 10, forming the pixel defining layer includes:
S41. Forming a pixel-defining material layer on the second conductive layer, the protrusion, and an exposed surface of the base substrate; and
S43. Patterning the pixel-defining material layer to form a pixel defining layer with the opening.

In some embodiments, the method for fabricating an array substrate may further include forming a hole injection layer on the pixel defining layer. Wherein the hole injection layer has the gap for the light-emitting device layer, an orthographic projection of the gap on the base substrate at least partially overlaps with an orthographic projection of the projection portion on the base substrate.

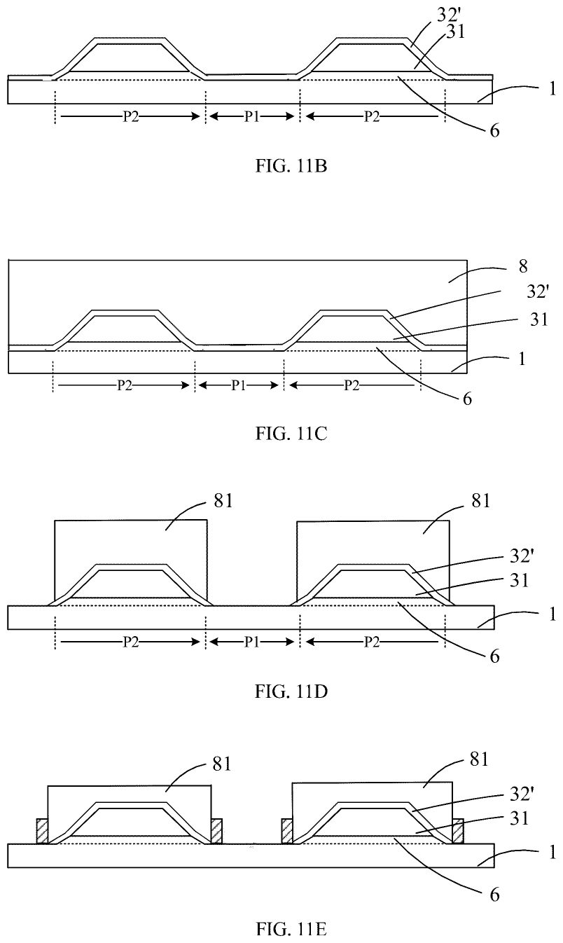

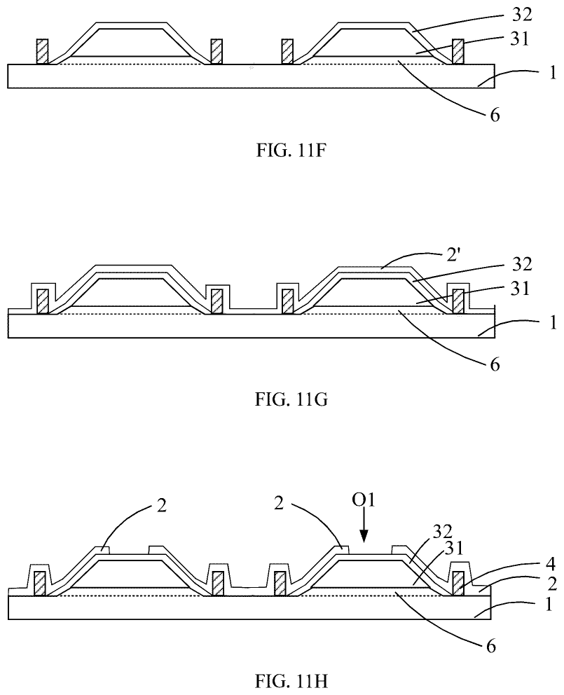

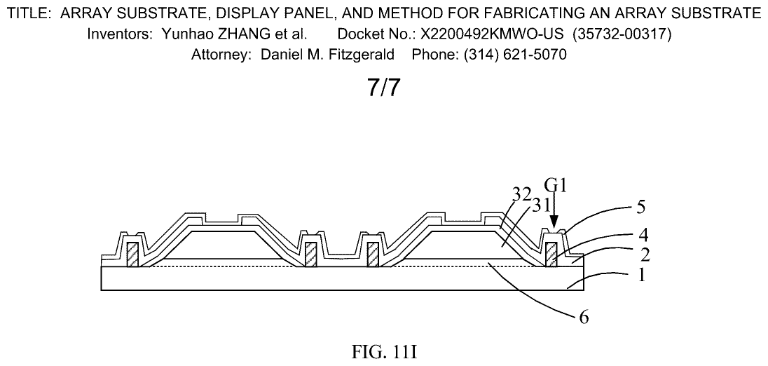

FIGS. 11A-FIG. 11I are flow diagrams of a method for fabricating an array substrate according to an embodiment of the present disclosure. As shown in FIGS. 11A-FIG. 11I, the method for fabricating an array substrate may include the following steps:

As shown in FIG. 11A, a base substrate 1 is provided, and a first conductive layer 31 is formed on the base substrate 1. The first conductive layer may, for example, include at least one of the following: Al, Ag, other highly reflective material, or a mixture thereof. Optionally, as shown in FIG. 11A, the base substrate 11 may be provided with a drive circuit layer 6. The drive circuit layer may be used to drive individual sub-pixels. As shown in FIG. 11A, the base substrate of the array substrate according to an embodiment of the present disclosure has a recessed portion P1 and a non-recessed portion P2. The recessed portion P1 is between the first conductive layer 31. An Orthographic projection of the first conductive layer 31 on the base substrate 1 falls within the non-recessed portion P2. The non-recessed portion P2 includes a first sub-portion 6 projecting in a direction perpendicular to the base substrate 1 and with respect to the recessed portion P1 toward the first conductive layer 31, wherein the first sub-portion 6 has a fifth surface S5 facing toward the first conductive layer 31 and a sixth surface S6 facing away from the first conductive layer 31. An orthographic projection of the fifth surface S5 on the base substrate falls within an orthographic projection of the sixth surface S6 on the base substrate and the area of the fifth surface S5 may be smaller than the area of the sixth surface S6.

As shown in FIG. 11B, a second conductive material layer 32′ is formed on the first conductive layer 31. The second conductive material layer may include a transparent conductive material such as ITO. For example, the second conductive material layer may be formed by sputtering.

As shown in FIG. 11C, a photoresist layer 8 is formed on the second conductive material layer. The inventors have found that setting the thickness of the photoresist layer in a range of about 0.35 μm to about 0.6 μm could facilitate the resolution of the crosstalk problem caused by current leakage between subpixels and can avoid the cathode puncture phenomenon. If the thickness of the photoresist is too low, the light emitting device layer into which the hole injection layer is injected cannot be spaced apart. If the thickness of the photoresist is too high, cathodic puncture may be caused.

As shown in FIG. 11D, the photoresist layer 8 is patterned to form a photoresist-retained portion 81 corresponding to the second conductive layer and a photoresist-removed portion 82 exposing the second conductive material layer.

As shown in FIG. 11E, the exposed portion of the second conductive material layer is etched to form the second conductive portion 32 and to form the protrusion 4. This etching step may also result in a thinning of the photoresist-retained portion. In this way, by utilizing the etching process to generate the protrusion, no additional steps are added, and instead, the process is simplified, and an unexpected effect of solving the problem of color crosstalk caused by leakage between sub-pixels and avoiding the cathode puncture phenomenon is achieved.

As shown in FIG. 11F, the photoresist-retained portion is removed. The steps of FIG. 11C-FIG. 11F can be performed in a high-pressure environment and a highly fluorinated atmosphere. For example, the fluorine content may be above 90% and the pressure may be about 15-17 millitorr. In performing the step shown in FIG. 11F, the photoresist removal can be performed using only a low concentration of photoresist removal solution, retaining the protrusion formed during the etching process. For example, an NMP photoresist removal solution with a concentration of about 0.38% may be employed.

For the structure obtained in FIG. 11F, although not shown, the recessed portion P1 may nevertheless have an intermediate portion 11 between the protrusions 4 and an edge portion 12 disposed between the protrusions 4 and disposed on either side of the intermediate portion 11. In a direction perpendicular to the base substrate 1, a height of the edge portion 12 is lower than a height of the intermediate portion 11 (for example, see FIG. 3). This structure can result from over-etching of the second conductive layer.

As shown in FIG. 11G, a pixel-defining material layer 2′ is formed on the exposed surfaces of the second conductive layer 32, the protrusion 4, and the base substrate 1.

As shown in FIG. 11H, the pixel-defining material layer 2′ is patterned to form a pixel defining layer 2 with an opening O1. Specifically, the pixel defining layer may be formed by applying a photoresist to the pixel defining layer, followed by exposure development and the like.

As shown in FIG. 11I, a hole injection layer 5 is formed on the pixel defining layer, and wherein the hole injection layer 5 has a gap G1. Specifically, the hole injection layer can be formed by vapor deposition.

Certain specific embodiments have been described, and these embodiments are only shown by way of example and are not intended to limit the scope of the present disclosure. In fact, the novel embodiments described herein can be implemented in various other forms; in addition, various omissions, substitutions and changes in the form of the embodiments described herein can be made without departing from the spirit of the present disclosure. The appended claims and their equivalents are intended to cover such forms or modifications that fall within the scope and spirit of the present disclosure.

What is claimed is:

1. An array substrate, comprising:
a base substrate;
a pixel defining layer with an opening on the base substrate;
a light emitting device layer comprising first electrodes between the base substrate and the pixel defining layer, wherein an orthographic projection of the first electrode on the base substrate overlaps at least partially with an orthographic projection of the opening on the base substrate; and
at least one protrusion on the base substrate and around the first electrode,
wherein the light emitting device layer has a gap, and wherein an orthographic projection of the gap on the base substrate overlaps at least partially with an orthographic projection of the protrusion on the base substrate.

2. The array substrate according to claim 1, wherein the first electrode has a first surface facing the base substrate and a second surface facing away from the base substrate, and the protrusion has a third surface facing the base substrate and a fourth surface facing away from the base substrate, wherein, compared with the second surface of the first electrode, the fourth surface of the protrusion is closer to the base substrate.

3. The array substrate according to claim 2, wherein, in a direction perpendicular to the base substrate, a height difference between the second surface of the first electrode and the fourth surface of the protrusion is in a range of 90 Å to 240 Å.

4. The array substrate according to claim 1, wherein the protrusion surrounds the first electrode.

5. The array substrate according to claim 1, wherein the protrusion is in contact with the first electrode.

6. The array substrate according to claim 1, wherein the first electrode comprises a first conductive layer and a second conductive layer, and wherein the second conductive layer covers a surface of the first conductive layer away from the base substrate and a side surface of the first conductive layer.

7. The array substrate according to claim 6, wherein a side of the base substrate close to the first electrode has a recessed portion and a non-recessed portion, the recessed portion being between the first conductive layer, and wherein an orthographic projection of the first conductive layer on the base substrate falls within the non-recessed portion.

8. The array substrate according to claim 7, wherein the non-recessed portion comprises a first sub-portion projecting in a direction perpendicular to the base substrate and with respect to the recessed portion toward the first conductive layer, wherein the first sub-portion has a fifth surface facing toward the first conductive layer and a sixth surface facing away from the first conductive layer, and wherein an orthographic projection of the fifth surface on the base substrate falls within an orthographic projection of the sixth surface on the base substrate.

9. The array substrate according to claim 8, wherein the first sub-portion further comprises a side surface connecting the fifth surface and the sixth surface, and wherein the second conductive layer further covers the side surface of the first sub-portion and extending to the protrusion.

10. The array substrate according to claim 9, wherein an angle between the side surface of the first sub-portion and the sixth surface is an acute angle.

11. The array substrate according to claim 9, wherein the recessed portion has an intermediate portion between the protrusions and an edge portion disposed between the protrusions and on either side of the intermediate portion, and wherein, in a direction perpendicular to the base substrate, a height of the edge portion is lower than a height of the intermediate portion.

12. The array substrate according to claim 1, wherein the pixel defining layer covers a side surface of the first electrode and a surface of the protrusion away from the base substrate and a side surface of the protrusion.

13. The array substrate according to claim 1, wherein a height of the protrusion in a direction perpendicular to the base substrate is greater than a minimum width of the protrusion in a direction parallel to the base substrate.

14. The array substrate according to claim 1, wherein the protrusion comprises at least one of an organic material or an inorganic material.

15. The array substrate according to claim 2, wherein an orthographic projection of the third surface of the protrusion on the base substrate overlies an orthographic projection of the fourth surface of the protrusion on the base substrate.

16. The array substrate according to claim 1, wherein, in a direction parallel to the base substrate, the protrusion has a width in a range of 0.02 μm to 0.03 μm.

17. The array substrate according to claim 1, wherein the light-emitting device layer comprises a light-emitting function layer away from the first electrode, and wherein a thickness of the projection is greater than a thickness of the light-emitting function layer.

18. A display device comprising an array substrate according to any one of claims 1-12.

19. A method for fabricating an array substrate, comprising:
providing a base substrate;
forming a pixel defining layer with an opening on the base substrate;
forming a first electrode between the base substrate and the pixel defining layer, wherein an orthographic projection of the first electrode on the base substrate overlaps at least partially with an orthographic projection of the opening on the base substrate;
forming at least one protrusion on the base substrate and around the first electrode; and
forming a light emitting device layer on the pixel defining layer, wherein the light emitting device layer has a gap, and wherein an orthographic projection of the gap on the base substrate overlaps at least partially with an orthographic projection of the protrusion on the base substrate.

20. The method according to claim 14, wherein the first electrode has a first surface facing the base substrate and a second surface facing away from the base substrate, and the protrusion has a third surface facing the base substrate and a fourth surface facing away from the base substrate, wherein compared with the second surface of the first electrode substrate, the fourth surface of the protrusion is closer to the base substrate, wherein the first electrode comprises a first conductive layer and a second conductive layer, the second conductive layer covering a surface of the first conductive layer away from the substrate and a side surface of the first conductive layer, and wherein forming the first electrode and the protrusion comprises:
forming the first conductive layer on the base substrate;
forming a second conductive material layer on a surface of the first conductive layer away from the base substrate, a side surface of the first conductive layer and an exposed surface of the base substrate;
forming a photoresist layer on the second conductive material layer;
patterning the photoresist layer to form a photoresist-retained portion corresponding to the second conductive layer and a photoresist-removed portion exposing the second conductive material layer;
etching an exposed portion of the second conductive material layer to form the second conductive portion and to form the protrusion; and
removing the photoresist-retained portion.
